(19) United States
(12) Patent Application Publication
(10) Pub. No.: US 2023/0409083 A1
(43) Pub. Date: Dec. 21, 2023

(54) DISPLAY DEVICE AND MANUFACTURING METHOD THEREOF

(71) Applicant: Samsung Display Co., LTD., Yongin-si (KR)

(72) Inventors: Seung Wook KWON, Yongin-si (KR); Se Hoon JEONG, Yongin-si (KR); Woo Yong SUNG, Yongin-si (KR)

(73) Assignee: Samsung Display Co., LTD., Yongin-si (KR)

(21) Appl. No.: 18/302,950

(22) Filed: Apr. 19, 2023

(30) Foreign Application Priority Data
Jun. 16, 2022 (KR) 10-2022-0073257

(51) Int. Cl. G06F 1/16; C09D 183/08; B32B 17/10

(52) U.S. Cl. CPC G06F 1/1652; C09D 183/08; B32B 17/1055; B32B 17/10256; B32B 17/10146; G06F 2200/16

(57) ABSTRACT

A display device includes a display panel, an organic layer disposed on a surface of the display panel, a polysilazane layer disposed on the organic layer and including a spaced region, and a resin layer disposed in the spaced region of the polysilazane layer. An elastic modulus of the resin layer is lower than an elastic modulus of the polysilazane layer.

### CROSS-REFERENCE TO RELATED APPLICATION(S)

This application claims priority to and benefits of Korean Patent Application No. 10-2022-0073257 under 35 U.S.C. § 119, filed on Jun. 16, 2022, in the Korean Intellectual Property Office (KIPO), the entire contents of which are incorporated herein by reference.

### BACKGROUND

### 1. Technical Field

The disclosure relates to a display device and a manufacturing method thereof.

### 2. Description of the Related Art

With recent development of display-related technologies, display devices that may be transformed at a stage of use such as folding, rolling in a roll shape, or stretching like a rubber band are being researched and developed. Since these display devices may be transformed into various forms, a demand for both of the large-sized display at the use stage and the down-sized display for portability may be satisfied.

In the case of such a flexible display device, as a stress of greater than a breaking strength due to excessive bending or repeated stress due to repetitive bending is applied to the display device, there are problems in that the lifespan of the display device may be shortened, and elements and wiring may be damaged.

The flexible display device has a thin thickness for the bending, and impact resistance may be reduced, and there is a problem that the device may be damaged.

The above information disclosed in this Background section is only for enhancement of understanding of the background of the disclosure, and therefore it may contain information that does not form the prior art that is already known in this country to a person of ordinary skill in the art.

### SUMMARY

Embodiments provide a display device having excellent durability and excellent flexibility.

A display device according to an embodiment may include a display panel, an organic layer disposed on a surface of the display panel, a polysilazane layer disposed on the organic layer and including a spaced region, and a resin layer disposed in the spaced region of the polysilazane layer. An elastic modulus of the resin layer may be lower than an elastic modulus of the polysilazane layer.

The polysilazane layer may include an inorganic polysilazane or an organic polysilazane.

The polysilazane layer may include at least one of a compound represented by Chemical Formula 1 and a compound represented by Chemical Formula 2:

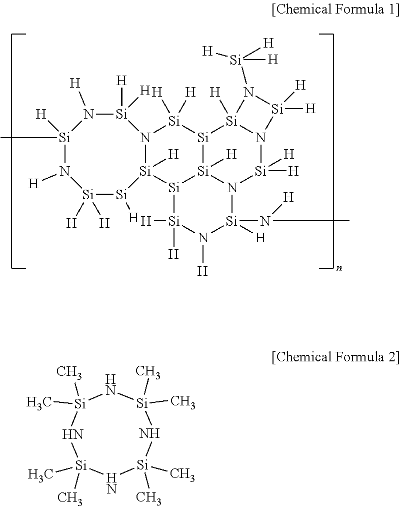

In Chemical Formula 1, n may be an integer between 1 and 10000.

The polysilazane layer may further include inorganic nanoparticles.

A content of the inorganic nanoparticles may be in a range of about 5 wt % to about 30 wt % of the polysilazane layer.

A thickness of the polysilazane layer may be in a range of about 5 um to about 100 um in a cross-sectional view.

An elastic modulus of the display device may be in a range of about 5 GPa to about 10 GPa.

The organic layer may include a polyimide.

An elastic modulus of the resin layer may be in a range of about 10 MPa to about 1 GPa.

The resin layer may be provided in plural.

The display device may include a folding part and a folding periphery, and the resin layer may be disposed on the bending part.

A shape of the resin layer in a cross-sectional view may be a curved shape, a semicircular shape, a quadrangular shape, a trapezoidal shape, or an inverted trapezoidal shape.

The display device may further include an organic auxiliary layer disposed on a surface of each of the polysilazane layer and the resin layer may be further included.

The organic auxiliary layer and the organic layer may include a same material.

A manufacturing method of a display device according to an embodiment may include preparing a substrate, forming a resin layer on an area of the substrate, forming a polysilazane layer on another area of the substrate, forming an organic layer on the resin layer and the polysilazane layer, forming a display panel on the organic layer, and removing the substrate. An elastic modulus of the resin layer may be lower than an elastic modulus of the polysilazane layer.

The substrate may be a glass substrate.

The forming of the resin layer may be performed by an inkjet process.

The removing of the substrate may be performed by an etching process.

The manufacturing method may further include forming an organic auxiliary layer on the substrate between the preparing of the substrate and the forming of the resin layer.

The removing of the substrate may be performed by laser irradiation.

A foldable electronic device according to an embodiment may include a display panel, an organic layer disposed on a surface of the display panel, a polysilazane layer disposed on the organic layer and including a spaced region, and a resin layer disposed in the spaced region of the polysilazane layer. An elastic modulus of the resin layer may be lower than an elastic modulus of the polysilazane layer.

The foldable electronic device may be a mobile phone or a tablet device.

The foldable electronic device may further include a folding part and a folding periphery, wherein the resin layer may be disposed on the folding part.

The polysilazane layer may be disposed on the folding periphery.

According to embodiments, the display device with excellent durability while having an excellent flexibility characteristic may be provided.

### BRIEF DESCRIPTION OF THE DRAWINGS

FIG. 1 is a schematic cross-sectional view of a display device according to an embodiment.

FIG. 2 is a schematic cross-sectional view of a display device in a folded state according to the embodiment.

FIG. 3 is a schematic cross-sectional view of a display device in a folded state according to the embodiment.

FIG. 4 is a schematic cross-sectional view of a display device according to another embodiment.

FIG. 5 is a schematic cross-sectional view of a display device according to an embodiment.

FIG. 6 is a schematic cross-sectional view of a display device according to an embodiment.

FIG. 7 is a schematic cross-sectional view of a display device according to an embodiment

FIG. 8 is a schematic cross-sectional view of a display device including a polyimide organic layer without a polysilazane layer.

FIG. 9 is a schematic cross-sectional view of a display device including a polysilazane layer and a polyimide organic layer.

FIG. 10 is a schematic cross-sectional view of a pad part of a display device including a polyimide organic layer without a polysilazane layer.

FIG. 11 is a schematic cross-sectional view of a pad part of a display device including a polysilazane layer and a polyimide organic layer.

FIG. 12 to FIG. 16 are schematic cross-sectional views showing a manufacturing method of a display device according to an embodiment.

FIG. 17 to FIG. 22 are schematic cross-sectional views showing a manufacturing method of a display device including an organic auxiliary layer.

FIG. 23 is a schematic cross-sectional view of a display device in a folded state manufactured by the manufacturing method according to an embodiment.

FIG. 24 is a schematic cross-sectional view of a display device in a folded state manufactured by the manufacturing method according to an embodiment.

FIG. 25 is a schematic diagram showing a mobile phone in which a polysilazane layer and a resin layer are applied as a substrate according to the embodiment.

FIG. 26 is a schematic diagram showing a tablet device in which a polysilazane layer and a resin layer are applied as a substrate according to the embodiment.

### DETAILED DESCRIPTION OF THE EMBODIMENTS

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clearly describe the disclosure, parts that are not connected with the description will be omitted, and the same elements or equivalents are referred to by the same reference numerals throughout the specification.

Further, since sizes and thicknesses of constituent members shown in the accompanying drawings are arbitrarily given for better understanding and ease of description, the disclosure is not limited to the illustrated sizes and thicknesses. In the drawings, the thicknesses of layers, films, panels, regions, etc., are exaggerated for clarity. In the drawings, for better understanding and ease of description, thicknesses of some layers and areas are excessively displayed.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present.

Spatially relative terms, such as “beneath”, “below”, “under”, “lower”, “above”, “upper”, “over”, “higher”, “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below”, for example, can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a”, “an”, and “the” are intended to include the plural forms as well, unless the context clearly indicates otherwise. Moreover, the terms “comprises”, “comprising”, “includes”, and/or “including” when used in this specification, specify the presence of stated features, integers, steps, operations, elements, components, and/or groups thereof, but do not preclude the presence or addition of one or more other features, integers, steps, operations, elements, components, and/or groups thereof.

In the specification, the phrase “in a plan view” means when an object is viewed from above, and the phrase “in a cross-sectional view” means when a cross-section taken by vertically cutting an object portion is viewed from the side.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

A manufacturing method of a display device according to an embodiment of the disclosure will be described in detail with reference to accompanying drawings.

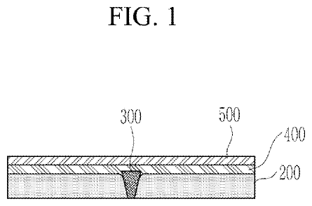

FIG. 1 is a schematic cross-sectional view of a display device according to an embodiment. Referring to FIG. 1, a display device according to the embodiment may include an organic layer 400. A display panel 500 may be disposed on a surface of the organic layer 400, and a polysilazane layer 200 and a resin layer 300 may be disposed on another surface. For example, as shown in FIG. 1, the display device according to the embodiment may not include a separate glass substrate, and the polysilazane layer 200 and the resin layer 300 may function as a substrate. The polysilazane layer 200 may have a high hardness and a relatively high elastic modulus, so it may stably support the display panel 500, and the resin layer 300 has a relatively low elastic modulus so that the display device may be readily folded. A display device including a glass substrate may shatter, so a glass substrate may not be suitable for a foldable display device, and in case that a substrate including polyimide is used instead of a glass substrate, the substrate may have an excellent flexibility characteristic, but may be susceptible to an external impact. However, the display device according to the embodiment may have an improved durability and flexibility characteristics by applying a polysilazane layer 200 and a resin layer 300 as a substrate instead of a glass substrate or a polyimide substrate.

Hereinafter, each constituent element of the display device according to the embodiment is described with reference to FIG. 1. In FIG. 1, the display panel 500 may be a portion that displays an image, and may include multiple transistors and a light-emitting element connected thereto.

The organic layer 400 may be disposed between the display panel 500, and the polysilazane layer 200 and the resin layer 300 and may flatten a step difference between the upper surfaces of the polysilazane layer 200 and the resin layer 300. The organic layer 400 may also fill a separation space that may be formed between the polysilazane layer 200 and the resin layer 300. The organic layer 400 may include a polyimide.

The polysilazane layer 200 may include an organic polysilazane or an inorganic polysilazane. The inorganic polysilazane may be composed of Si—H, Si—N, and N—H, and the organic polysilazane may include an organic material substituted. The polysilazane layer 200 may include a compound represented by Chemical Formula 1 or Chemical Formula 2 below. In Chemical Formula 1, n may be an integer between 1 and 10000. The compound represented by Chemical Formula 1 may be inorganic polysilazane, and the compound represented by Chemical Formula 2 may be organic polysilazane. According to an embodiment, the polysilazane layer 200 may include both of an organic polysilazane and an inorganic polysilazane.

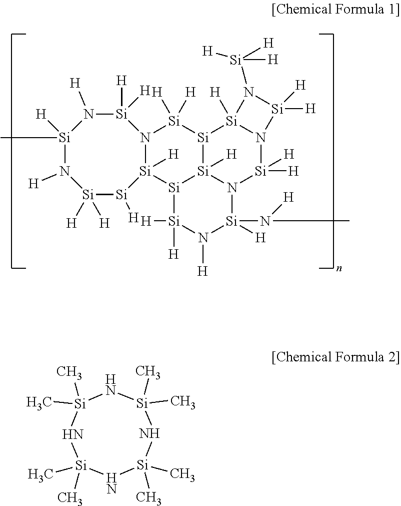

According to an embodiment, the polysilazane layer 200 may include inorganic nanoparticles. The inorganic nanoparticles may be aluminum oxide or graphene oxide.

The inorganic nanoparticles may be dispersed in the polysilazane layer 200. A content of the inorganic nanoparticles may be in a range of about 5 wt % to about 30 wt % of the polysilazane layer 200. In case that the polysilazane layer 200 includes inorganic nanoparticles, the strength of the polysilazane layer 200 may be further increased and the display panel 500 may be more stably supported.

An elastic modulus of the display device including the polysilazane layer 200 may be in a range of about 5 GPa to about 10 GPa. The polysilazane layer 200 may have a higher elastic modulus than the resin layer 300 and may stably support the display panel. The elastic modulus of the display device may increase as the thickness of the polysilazane layer 200 increases or as a content of polysilazane in the polysilazane layer 200 increases.

Pencil hardness of the polysilazane layer 200 may be 9H. Since the polysilazane layer 200 has a high pencil hardness, the polysilazane layer 200 may stably support the display panel. The thickness of the polysilazane layer 200 may be in a range of about 5 um to about 100 um. This may be a thickness range of the polysilazane layer 200 to secure durability and flexibility characteristics for the display device.

The polysilazane layer 200 may have a spaced region, and the resin layer 300 may be disposed in the spaced region. The resin layer 300 may have a relatively low elastic modulus. An elastic modulus of the resin layer 300 may be in a range of about 10 MPa to about 1 GPa. The resin layer 300 may include a polymer resin having a such elastic modulus. The resin layer 300 may function as a dam during forming of the polysilazane layer 200 during the manufacturing process. The resin layer 300 may have a low elastic modulus, so it can be readily folded by being stretched or shrunk during the folding. In the display device according to the embodiment, the region where the resin layer 300 is disposed may be a region in which the folding or the bending is performed. The An area of the resin layer 300 may be in a range of about 1% to about 5% of an area of the entire display device in a plan view, but is not limited thereto. According to an embodiment, more than one resin layer 300 may be disposed.

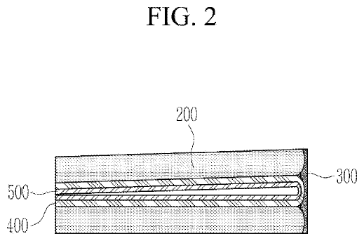

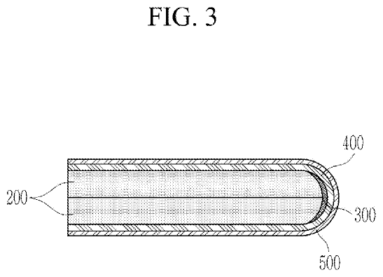

FIG. 2 and FIG. 3 are each a schematic cross-sectional view of a display device in a folded state according to the embodiment. As shown in FIG. 2, the display device according to the embodiment may be folded so that the display panel 500 is disposed inside. As shown in FIG. 2, as the resin layer 300 is stretched, the folding may be readily performed.

Referring to FIG. 3, the display device according to the embodiment may be folded so that the display panel 500 is disposed outward. The resin layer 300 may be also properly stretched and contracted to facilitate the folding.

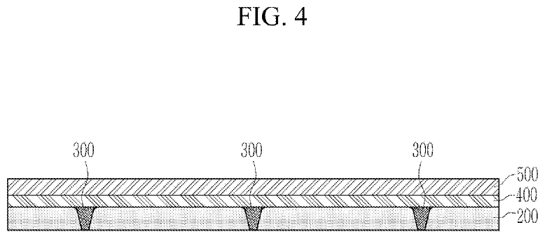

In FIG. 1 to FIG. 3, only one resin layer 300 is shown, but according to an embodiment, the display device may include multiple resin layers 300. For example, the polysilazane layer 200 may include multiple spaced regions, and multiple resin layers 300 may be disposed in the spaced regions. For example, the resin layer 300 may be provided in plural. FIG. 4 is a schematic cross-sectional view of a display device according to another embodiment. Referring to FIG. 4, the display device according to the embodiment may include multiple resin layers 300. The region where the resin layer 300 is disposed may be a region where the folding or the bending takes place, and as shown in FIG. 4, the display device including multiple resin layers 300 may be folded in multiple regions.

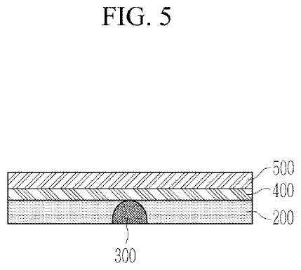

FIG. 1 and FIG. 4 show the configuration in which the resin layer 300 has a wide inverted trapezoid shape on the side close to the display panel 500, but this is only an embodiment, and the shape of the resin layer 300 is not limited thereto. FIG. 5 to FIG. 7 are each a schematic cross-sectional view of a display device according to an embodiment. FIG. 5 to FIG. 7 each shows another embodiment of the display device of FIG. 1. The display device according to the embodiments of FIG. 5 to FIG. 7 may differ from that of FIG. 1 at least in the shape of the resin layer 300. The detailed description of the same constituent elements is omitted.

Referring to FIG. 5, the resin layer 300 of the display device according to the embodiment may have a semicircular shape with a curved surface in a cross-sectional view. Since stress is not concentrated and is evenly distributed, the folding of the display device may be readily performed.

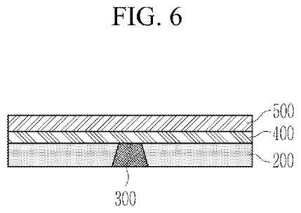

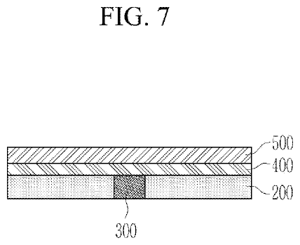

Referring to FIG. 6, the resin layer 300 of the display device according to the embodiment may have a trapezoid shape in a cross-sectional view. Referring to FIG. 7, the resin layer 300 of the display device according to the embodiment may have a quadrangle shape in a cross-sectional view. The various shapes of the resin layer 300 have been described above, but the resin layer 300 is not limited to the described shapes. For example, the resin layer 300 may have other shapes in consideration of the folding direction of the display device.

The display device according to the embodiment may include a polysilazane layer as a substrate instead of a glass substrate or a polyimide substrate, and a resin layer between the polysilazane layer to enable the folding. Therefore, the durability of the display device may be secured while securing a flexibility characteristic.

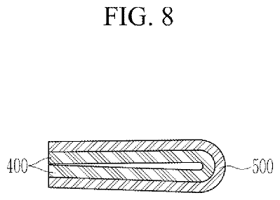

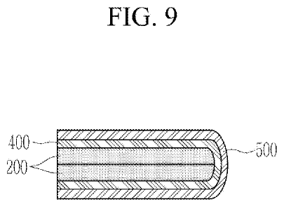

FIG. 8 is a schematic cross-sectional view of a display device including a polyimide organic layer without a polysilazane layer, and FIG. 9 is a schematic cross-sectional view of a display device including a polysilazane layer and a polyimide organic layer. Comparing FIG. 8 and FIG. 9, a spaced region may occur during the bending and the display device may not be stably bent in the case of FIG. 8, but the display panel 500 bent by the polysilazane layer 200 may be stably supported in the case of FIG. 9. Therefore, the stress may be minimized during the bending.

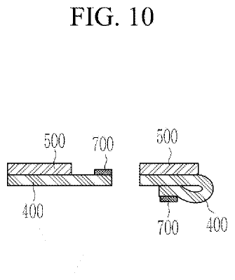

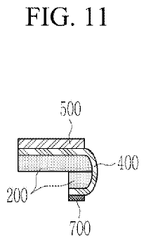

FIG. 10 schematic cross-sectional view of a pad part 700 of a display device including a polyimide organic layer 400 without a polysilazane layer 200, and FIG. 11 is a schematic cross-sectional view of a pad part 700 of a display device including a polysilazane layer 200 and a polyimide organic layer 400. In FIG. 10 and FIG. 11, each of the organic layer 400 and the polysilazane layer 200 is bent so that the pad part 700 faces the back surface of the display panel 500. Comparing FIG. 10 and FIG. 11, a spaced region may occur during the bending the display device may not be stably bent in the case of FIG. 10, but the display panel 500 bent by the polysilazane layer 200 may be stably supported in the case of FIG. 11. Therefore, stress may be minimized during the bending.

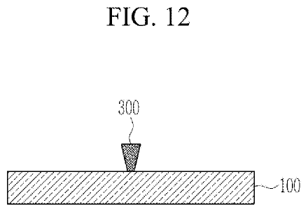

Hereinafter, a manufacturing method of the display device according to an embodiment of the disclosure is described in detail. FIG. 12 to FIG. 16 are schematic cross-sectional views showing a manufacturing method of a display device according to an embodiment.

Referring to FIG. 12, a glass substrate 100 may be prepared and a resin layer 300 may be formed on the glass substrate 100. For example, the resin layer 300 may be formed on an area of the glass substrate 100. The glass substrate 100 may be removed in a later step. The resin layer 300 may be formed by an inkjet process. In FIG. 12 to FIG. 16, the resin layer 300 is shown as having an inverted trapezoid shape as shown in FIG. 1, but it is not limited thereto, and the resin layer 300 may be formed in various shapes. By the flow during the inkjet process, the resin layer 300 may be formed in a shape having a curved surface as shown in FIG. 5. The description of the resin layer 300 is the same as described above. An elastic modulus of the resin layer 300 may be in a range of about 10 MPa to about 1 GPa. The resin layer 300 may be formed in the region where the display device is folded or bent, and one or more resin layer 300 may be formed. An area of the resin layer 300 may be in a range of about 1% to about 5% of an area of the entire display device in a plan view.

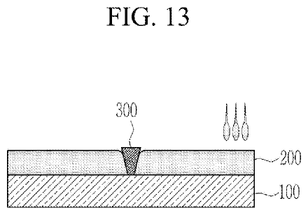

Referring to FIG. 13, a polysilazane layer 200 may be formed on the glass substrate 100. For example, the polysilazane layer 200 may be formed on another area of the glass substrate 100. The polysilazane layer 200 may be formed in a liquid form. For example, the polysilazane layer 200 may be formed by coating polysilazane and curing it. In the process of forming the polysilazane layer 200, the pre-formed resin layer 300 may function as a dam.

The description of the polysilazane layer 200 is the same as described above. The detailed description of the same constituent elements is omitted. For example, the polysilazane layer 200 may include an organic polysilazane or an inorganic polysilazane. The polysilazane layer 200 may include a compound represented by Chemical Formula 1 or Chemical Formula 2 below. According to an embodiment, the polysilazane layer 200 may include both of an organic polysilazane and an inorganic polysilazane.

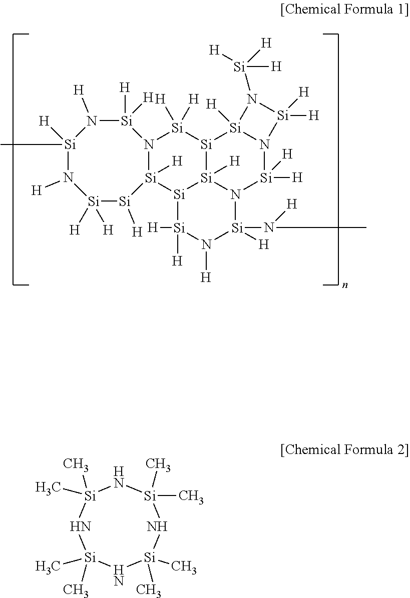

The polysilazane layer 200 may include inorganic nanoparticles. The inorganic nanoparticles may be aluminum oxide or graphene oxide. A content of the inorganic nanoparticles may be in a range of about 5 wt % to about 30 wt % of the polysilazane layer 200.

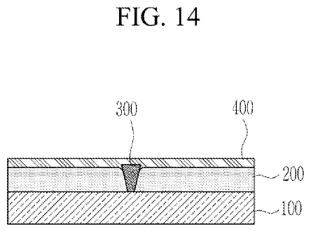

Referring to FIG. 14, an organic layer 400 may be formed. The organic layer 400 may be formed on the resin layer 300 and the polysilazane layer 200. The organic layer 400 may include a polyimide. The organic layer 400 may compensate and planarize the step difference between the polysilazane layer 200 and the resin layer 300, and may function as a barrier layer.

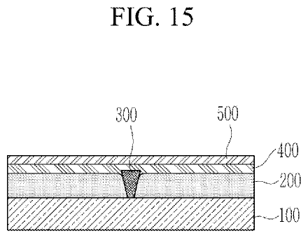

Referring to FIG. 15, a display panel 500 may be formed on the organic layer 400.

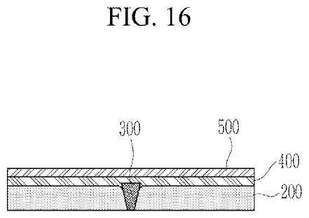

Referring to FIG. 16, the glass substrate 100 may be removed. An etching process may be used to remove the glass substrate 100. However, the disclosure is not limited thereto, and in another embodiment to be described later, the glass substrate 100 may be removed by another method.

FIG. 12 to FIG. 16 shows an embodiment in which the resin layer 300 and the polysilazane layer 200 are formed directly on the glass substrate 100, but according to an embodiment, an organic auxiliary layer 410 may be formed on the glass substrate 100. The glass substrate 100 may be removed by laser irradiation, and both surfaces of the resin layer 300 and the polysilazane layer 200 may be covered.

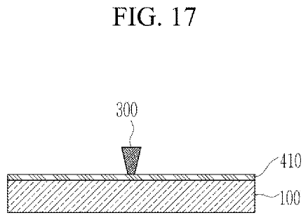

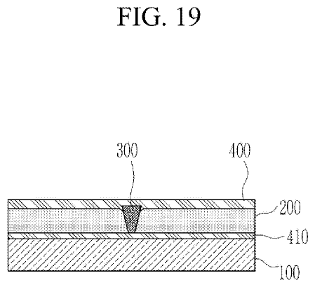

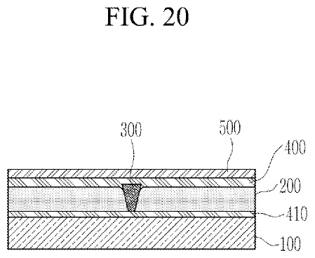

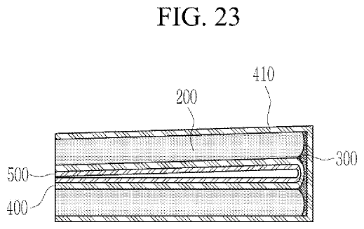

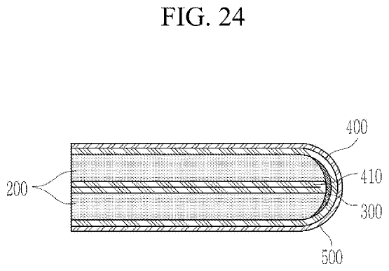

FIG. 17 to FIG. 22 are schematic cross-sectional views showing a manufacturing method of a display device including an organic auxiliary layer, and FIG. 23 and FIG. 24 are each a schematic cross-sectional view of a display device in a folded state manufactured by the manufacturing method according to an embodiment.

Referring to FIG. 17, after forming an organic auxiliary layer 410 on a glass substrate 100, a resin layer 300 may be formed on the organic auxiliary layer 410. The organic auxiliary layer 410 may include a polyimide. The process of forming the resin layer 300 on the organic auxiliary layer 410 may be same as that in FIG. 12, and thus is omitted.

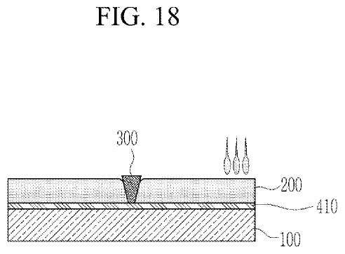

Referring to FIG. 18 to FIG. 20, a polysilazane layer 200, an organic layer 400, and a display panel 500 may be sequentially formed on the organic auxiliary layer 410. The detailed description of this process is same as that of FIG. 13 to FIG. 15, and thus is omitted.

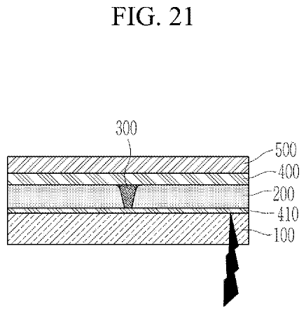

Referring to FIG. 21, the glass substrate 100 may be removed. Since the organic auxiliary layer 410 is disposed between the glass substrate 100 and the polysilazane layer 200, the glass substrate 100 may be removed by laser peeling. The process may be simpler than removing by etching.

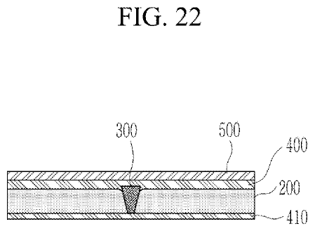

FIG. 22 shows the display device manufactured by the manufacturing process. Referring to FIG. 22, the display device according to the embodiment is same as the embodiment of FIG. 1 except that the display device further may include an organic auxiliary layer 410 under the polysilazane layer 200 and the resin layer 300. The detailed description of the same constituent elements is omitted. In the embodiment, the organic layer 400 and the organic auxiliary layer 410 may include the same material, for example, a polyimide.

FIG. 23 is a schematic cross-sectional view in which the display device of FIG. 22 is folded so that the display panel 500 faces inward, and FIG. 24 is a schematic cross-sectional view in which the display device of FIG. 22 is folded so that the display panel 500 faces outward. The resin layer 300 may be properly stretched or contracted during the folding, and the folded display device may be stably supported by the polysilazane layer 200.

As described above, in the display device according to the embodiment, the durability and flexibility characteristics of the display device may be simultaneously realized by applying a polysilazane layer 200 and a resin layer 300 as a substrate instead of a glass substrate or a polyimide substrate.

Such a display device may be applied to an electronic device such as a mobile phone or a tablet. These electronic devices may be foldable. Hereinafter, an electronic device to which such display device is applied is described.

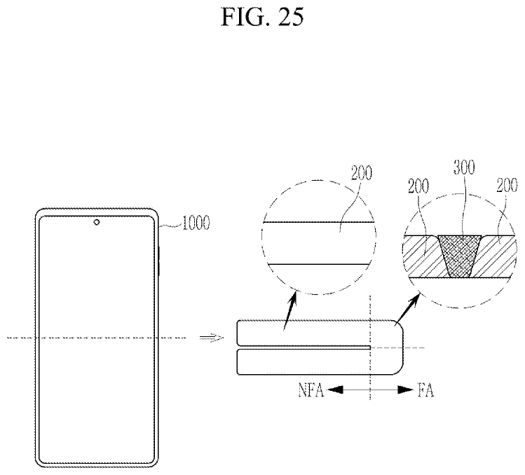

FIG. 25 is a schematic diagram showing a mobile phone 1000 in which a polysilazane layer 200 and a resin layer 300 are applied as a substrate according to the embodiment. In the mobile phone 1000 according to the embodiment, the substrate of the display device may have the same structure as that of FIG. 1 that is described above. For example, a separate glass substrate may be not included, and a polysilazane layer 200 and a resin layer 300 may function as a substrate. Therefore, as shown in FIG. 24, the mobile phone may be folded. A display device (shown as a mobile phone 1000 in FIG. 25) may include a folding part FA and a folding periphery NFA. The resin layer 300 may be disposed on the folding part FA where the mobile phone is folded, and the polysilazane layer 200 may be disposed on a folding periphery NFA.

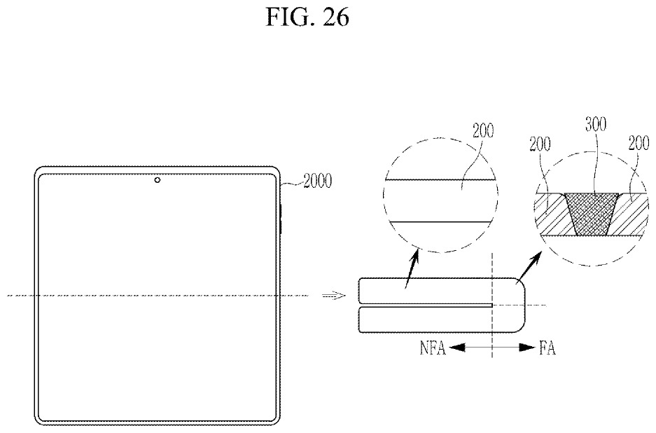

FIG. 26 is a schematic diagram showing a tablet device 2000 in which a polysilazane layer 200 and a resin layer 300 are applied as a substrate according to the embodiment. In the tablet device 2000 according to the embodiment, the substrate of the display device may have the same structure as that of FIG. 1 that is described above. For example, a separate glass substrate may be not included, and a polysilazane layer 200 and a resin layer 300 may function as a substrate. Therefore, as shown in FIG. 25, the tablet device may be folded. The resin layer 300 may be disposed on the folding part FA where the tablet device is folded, and the polysilazane layer 200 may be disposed on a folding periphery NFA.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A display device comprising:
a display panel;
an organic layer disposed on a surface of the display panel;
a polysilazane layer disposed on the organic layer and including a spaced region; and
a resin layer disposed in the spaced region of the polysilazane layer, wherein
an elastic modulus of the resin layer is lower than an elastic modulus of the polysilazane layer.

2. The display device of claim 1, wherein the polysilazane layer includes an inorganic polysilazane or an organic polysilazane.

3. The display device of claim 1, wherein
the polysilazane layer includes at least one of a compound represented by Chemical Formula 1 and a compound represented by Chemical Formula 2: 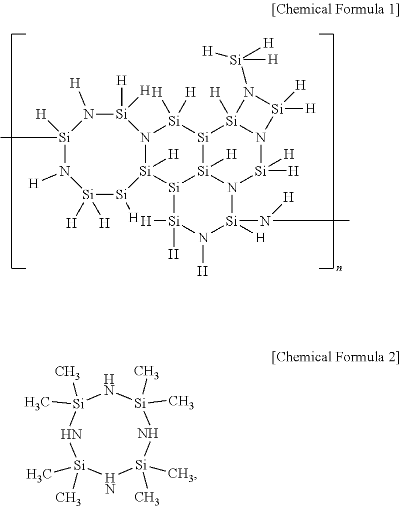
wherein in Chemical Formula 1,
n is an integer between 1 and 10000.

4. The display device of claim 1, wherein the polysilazane layer further includes inorganic nanoparticles.

5. The display device of claim 4, wherein a content of the inorganic nanoparticles is in a range of about 5 wt % to about 30 wt % of the polysilazane layer.

6. The display device of claim 1, wherein a thickness of the polysilazane layer is in a range of about 5 um to about 100 um.

7. The display device of claim 1, wherein an elastic modulus of the display device is in a range of about 5 GPa to about 10 GPa.

8. The display device of claim 1, wherein the organic layer includes a polyimide.

9. The display device of claim 1, wherein an elastic modulus of the resin layer is in a range of about 10 MPa to about 1 GPa.

10. The display device of claim 1, wherein the resin layer is provided in plural.

11. The display device of claim 1, wherein
the display device includes a folding part and a folding periphery, and
the resin layer is disposed on the folding part.

12. The display device of claim 1, wherein
a shape of the resin layer in a cross-sectional view is a curved shape, a semicircular shape, a quadrangular shape, a trapezoidal shape, or an inverted trapezoidal shape.

13. The display device of claim 1, further comprising:
an organic auxiliary layer disposed on a surface of each of the polysilazane layer and the resin layer.

14. The display device of claim 13, wherein the organic auxiliary layer and the organic layer include a same material.

15. A manufacturing method of a display device comprising:
preparing a substrate;
forming a resin layer on an area of the substrate;
forming a polysilazane layer on another area of the substrate;
forming an organic layer on the resin layer and the polysilazane layer;
forming a display panel on the organic layer; and
removing the substrate, wherein
an elastic modulus of the resin layer is lower than an elastic modulus of the polysilazane layer.

16. The manufacturing method of the display device of claim 15, wherein the substrate is a glass substrate.

17. The manufacturing method of the display device of claim 15, wherein the forming of the resin layer is performed by an inkjet process.

18. The manufacturing method of the display device of claim 15, wherein the removing of the substrate is performed by an etching process.

19. The manufacturing method of the display device of claim 15, further comprising:
forming an organic auxiliary layer on the substrate between the preparing of the substrate and the forming of the resin layer.

20. The manufacturing method of the display device of claim 19, wherein the removing of the substrate is performed by laser irradiation.

21. A foldable electronic device comprising:
a display panel;
an organic layer disposed on a surface of the display panel;
a polysilazane layer disposed on the organic layer and including a spaced region; and
a resin layer disposed in the spaced region of the polysilazane layer, wherein
an elastic modulus of the resin layer is lower than an elastic modulus of the polysilazane layer.

22. The foldable electronic device of claim 21, wherein the foldable electronic device is a mobile phone or a tablet device.

23. The foldable electronic device of claim 21, further comprising:
a folding part and a folding periphery, wherein
the resin layer is disposed on the folding part.

24. The foldable electronic device of claim 23, wherein the polysilazane layer is disposed on the folding periphery.
